(19) United States
(12) Patent Application Publication
(10) Pub. No.: US 2001/0017406 A1
(43) Pub. Date: Aug. 30, 2001

(54) STACKED STRUCTURE OF STACKABLE SEMICONDUCTOR PACKAGES AND METHOD OF STACKING SAME

(76) Inventor: JOON-KI HONG, CHOONGCHEONGBUK-DO (KR)

Correspondence Address: MORGAN, LEWIS & BOCKIUS, 1800 M STREET NW, WASHINGTON, DC, 20036-5869, US

(21) Appl. No.: 09/315,950

(22) Filed: May 21, 1999

(30) Foreign Application Priority Data
Jan. 11, 1999 (KR) 407/1999

(51) Int. Cl. H01L 23/02

(52) U.S. Cl. 257/686

(57) ABSTRACT

A structure of a stackable semiconductor package, includes a stacked semiconductor package in which a plurality of semiconductor packages are stacked, each semiconductor package having a plurality of external leads at side surfaces thereof, and conductive wires for electrically connecting the corresponding external leads of said semiconductor packages of said stacked semiconductor package. The stacked structure of stackable semiconductor packages and the method of stacking the same improves the productivity by using an automatic wiring technique for electrically connecting the corresponding external leads. In addition, since the thickness of each wire which is used for lastly transmitting signals can be adjusted, the flexibility thereof increases and thereby the reliability can be improved in the solder joint.

### BACKGROUND OF THE INVENTION

1. Field of the Invention

The present invention relates to a semiconductor package, and more particularly to a stacked structure of stackable semiconductor packages and a stacking method thereof.

2. Description of the Conventional Art

FIGS. 1 and 2 illustrate a structure of a conventional stacked semiconductor package 10 in which an upper semiconductor package 12 having a plurality of external leads 12a is stacked on a lower semiconductor package 11 having a plurality of external leads 11a, the external leads 12a having a one-to-one correspondence to the external leads 11a and each of the corresponding external leads 11a, 12a of the packages 11, 12 being electrically connected by a rail 13.

The upper and lower semiconductor packages 11, 12 have the same size and also the external leads 11a, 12a have the same size. Here, the external leads 11a, 12a respectively have a short length. while, the rail 13 has holes where the corresponding external leads 11a, 12a of the semiconductors 11, 12 are connected and are used for electrically connecting the external leads 11a, 12a of each vertical row of the stacked semiconductor package 10, a bottom portion of each rail 13 is bent in the J, L or gull-type.

FIGS. 4A through 4c sequentially illustrate the method of stacking the conventional stackable semiconductor package. Here, FIG. 4A is a cross-sectional view taken along the line IV-IV′ of FIG. 3.

First, as can be seen in FIGS. 4A and 4B, a plurality of semiconductor packages respectively having external leads 11a which are exposed at a side surface, the semiconductor packages having the same size and the external leads 11a being identically formed. Hereinafter, a lower-positioned semiconductor package is referred to a low semiconductor package 11 and an upper-positioned semiconductor package to a high semiconductor package.

In FIG. 4B, the high semiconductor package 12 is stacked on the lower semiconductor package 11 by an adhesive member. Each external lead 12a of the high semiconductor package 12 has a one-to-one correspondence to each external lead 11a of the low semiconductor package 11, the size and shape of the leads being identical.

As shown in FIG. 4C, the rails 13 which have holes at which the external leads 11a, 12a correspond to each other are connected with the leads 11a, 12a in order to electrically connect the corresponding external leads 11a, 12a of the packages 11, 12. In other words, the rails 13 are fixed to the external leads 11a, 12a. Therefore, the fabrication of the conventional stacked semiconductor package 10 is completed.

More specifically, the rails 13 are electrically insulated from each other and used for electrically connecting the external leads 11a, 12a of each vertical row of the stacked semiconductor package 10, the bottom portion thereof being bent in various types such as the J, L or gull-type for thereby being suitably used for the stacked package.

However, in order to electrically connect the corresponding external leads, it is required to fix the rail to the external leads one by one, which results in a drop in productivity because the operation is not automated.

### SUMMARY OF THE INVENTION

Accordingly, the present invention is directed to a stacked structure of stackable semiconductor packages and a stacking method thereof which obviates the problems and disadvantages due to the conventional art.

An object of the present invention is to provide a stacked structure of stackable semiconductor packages that improves the productivity of a stackable semiconductor package.

To achieve these and other advantages and in accordance with the purpose of the present invention, as embodied and broadly described, there is provided a stacked structure of stackable semiconductor packages which includes a stacked semiconductor package in which a plurality of semiconductor packages are stacked, each semiconductor package having a plurality of external leads at side surfaces thereof, and conductive wires for electrically connecting the corresponding external leads of the semiconductor packages of the stacked semiconductor package.

Also, there is provided a method of stacking a stackable semiconductor package including stacking a plurality of stackable semiconductor packages by an adhesive member, each semiconductor package having a plurality of external leads at side surfaces thereof, electrically connecting the corresponding upper and lower external leads of the stackable semiconductor packages in the stacked semiconductor package structure by using a plurality of conductive wires, reflowing for firmly attaching the wires to the corresponding external leads, and cutting and removing portions of the wires to electrically insulate the corresponding upper and lower external leads from the adjacent external leads and from the opposite external leads.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a perspective view of a stacked sructure of the conventional stackable semiconductor packages;

FIG. 2 is a cross-sectional view taken along the line 11-11′ of FIG. 1;

FIG. 3 is a perspective view of a lower semiconductor package of FIG. 1;

FIGS. 4A through 4C sequentially illustrate a method of stacking the conventional stackable semiconductor package, FIG. 4A being a cross-sectional view taken along the line IV-IV′ of FIG. 3;

FIG. 5 is a perspective view of a stacked structure of stackable semiconductor packages according to the present invention;

FIG. 6 is a cross-sectional view taken along the line VI-VI′ of FIG. 5;

FIG. 7 is a perspective view of a lower semiconductor package in FIG. 5; and

FIGS. 8A through 8E sequentially illustrate a method of stacking the stackable semiconductor package according to the present invention, FIG. 8A being a cross-sectional view taken along the line VIII-VIII′ of FIG. 7.

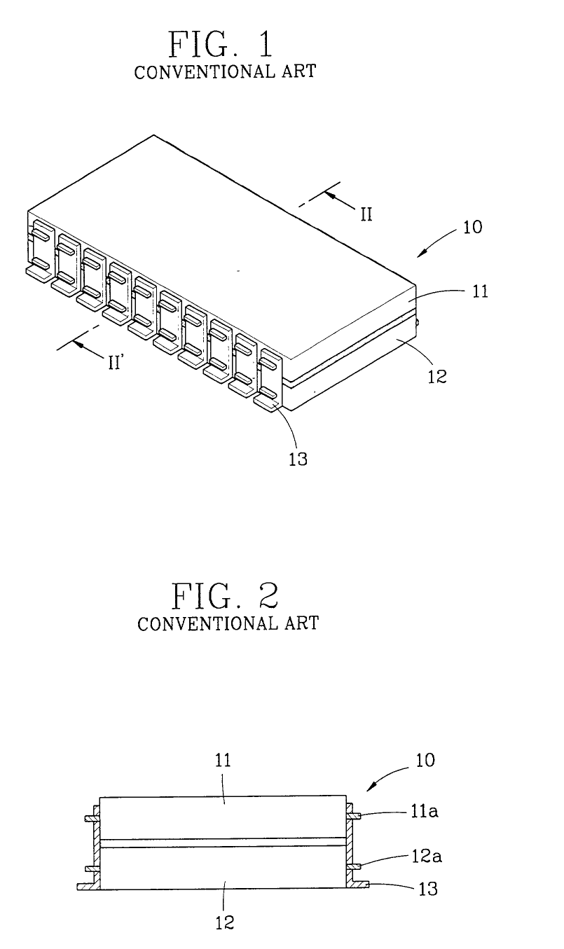

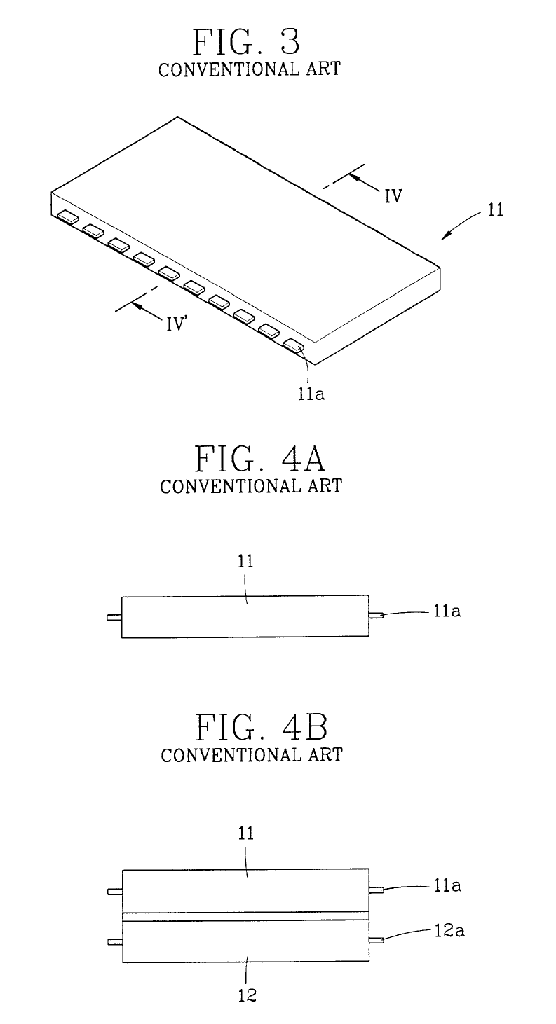

### DETAILED DESCRIPTION OF THE INVENTION

Reference will now be made in detail to the preferred embodiment of the present invention, examples of which are illustrated in the accompanying drawings.

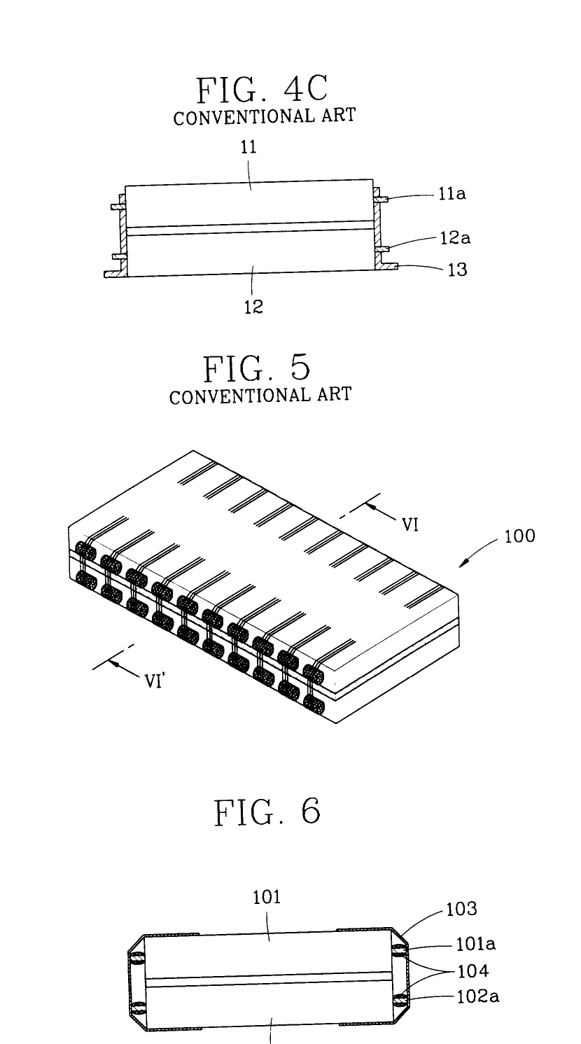

First, as shown in FIGS. 5 and 6, the stacked structure of semiconductor packages 100 according to the present invention. As shown therein, there is provided a lower semiconductor package 101 having a plurality of external leads 101a, and an upper semiconductor package 102 having a plurality of external leads 102a is stacked on the lower semiconductor package 101, the external leads 102a having a one-to-one correspondence with the external leads 101a. Here, it is noted that the corresponding external leads 101a, 102a of the packages 101, 102 are electrically connected by conductive wires 103, and the correspondingly paired external leads 101a, 102a are insulated from adjacent external leads.

The lower and upper semiconductor packages 101, 102 may have the same size or different size, however the external leads 101a, 102a are the same in size. Here, the external leads 101a, 102a are preferably short formed. The conductive wires 103 are mainly formed of copper which is plated with lead or any other suitable material.

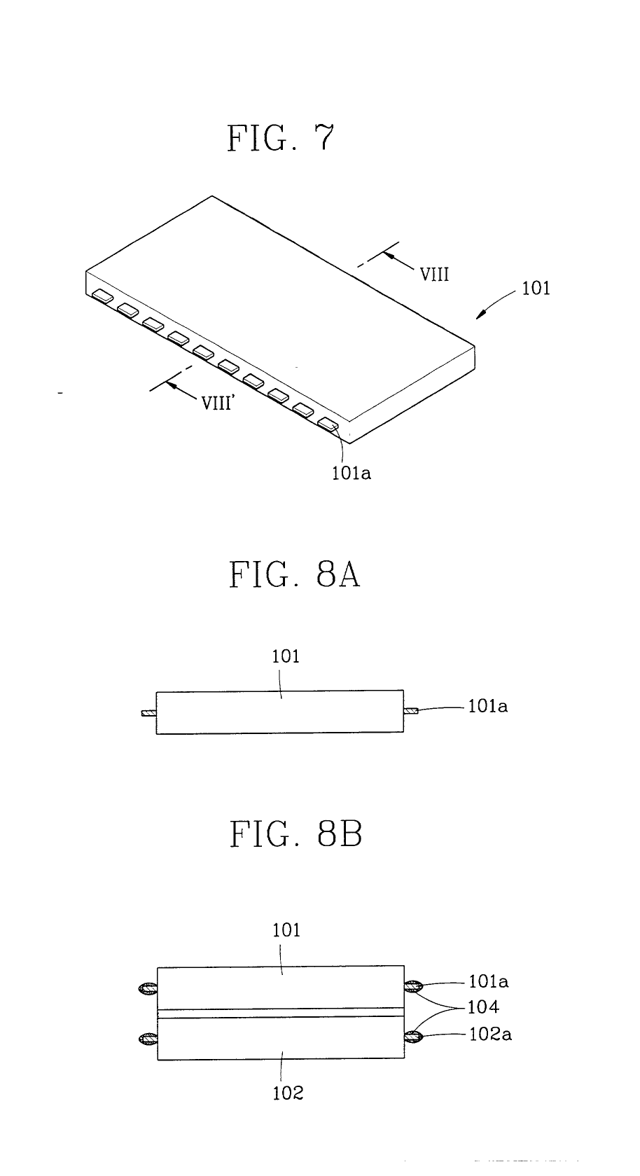

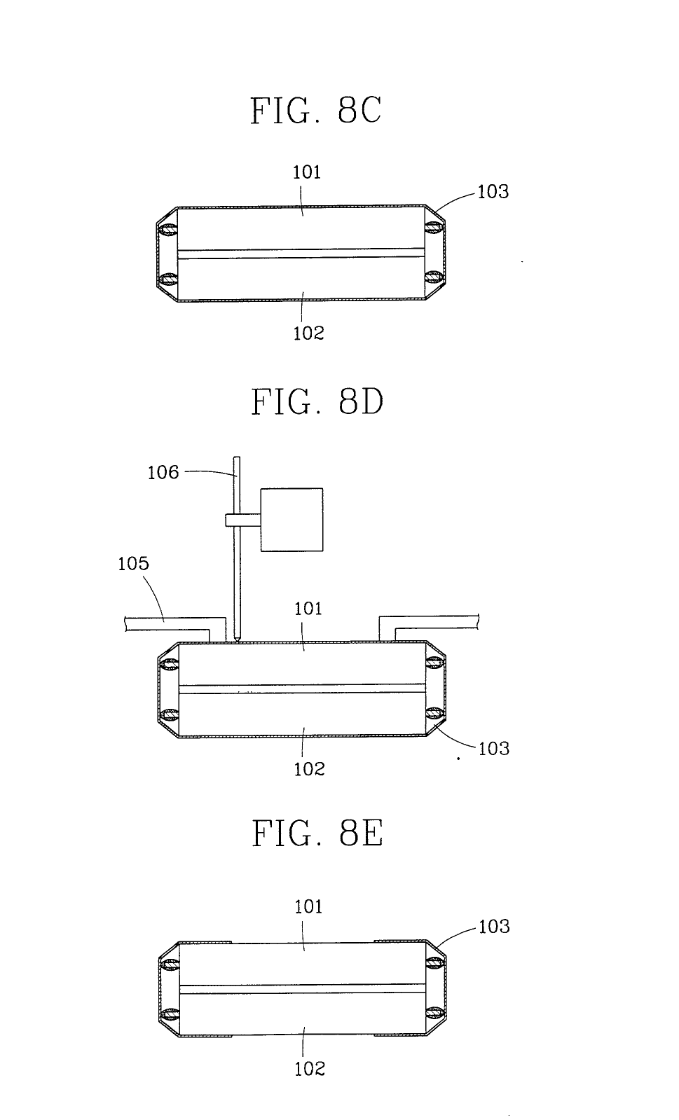

Further, FIGS. 8A through 8E sequentially illustrate a method of stacking the stackable semiconductor packages according to the present invention. FIG. 8A is a cross-sectional view taken along the line VIII-VIII′ of FIG. 7. First, as shown in FIGS. 8A and 8B, general semiconductor packages 101, 102 are provided and external leads 101a, 102a of the semiconductor packages 101, 102, respectively, are comparatively short formed by trimming. Next, the semiconductor packages 101,102 are stacked by an adhesive member so that the external leads 101 a correspond to the external leads 102a by one to one. Here, the external leads 101a, 102a are plated with lead and during the trimming process a section of each external lead is formed flat or concave.

The semiconductor packages 101,102 may have the same or different size, and each size of the external leads 101a, 102a is identical.

Next, as shown in FIG. 8C. the stacked structure of the semiconductor structures 100 is wound by conductive wires 103 in order to electrically connect the corresponding upper and lower external leads 101a, 102a of the semiconductor package 101, 102, each wire 103 being formed of copper placed with lead or other conductive material and being wound at a regular pitch by an automatic wiring apparatus.

Further, a solder paste 104 is selectively applied to the external leads 101a, 102a to achieve the electric and physical connection between the conductive wires 103 and the external leads 101a, 102a. After applying the solder paste 104, an infrared reflow or a solder deep process is performed to firmly fix the wires 103 to the external leads 101a, 102a. It is noted that the external leads 101a, 102a can be applied before winding the wires 103 round the stacked semiconductor package 100.

As shown in FIGS. 8D and 8E, to have a landing zone of a printed circuit board wherein the stacked semiconductor package 100 will be mounted, a predetermined portion of each wire 103 winding the upper and lower surfaces of the package 100 is fixed by a wire fix plate and removed by using a cutting machine 106. Accordingly, the portions of the wire 103 which is not connected with the external leads 101a, 102a are removed, for thereby insulating adjacent external leads.

Accordingly, according to the stackable semiconductor package according to the present invention, the leads which are the external signal terminals are electrically connected by the automatic wiring technique, thus improving the productivity.

Also, since the thickness of each wire which is used for lastly transmitting signals can be adjusted, the flexibility thereof increases and thereby the reliability can be improved in the solder joint.

It will be apparent to those skilled in the art that various modifications and variations can be made in the stacked structure of the stackable semiconductor packages and the stacking method thereof of the present invention without departing from the spirit or scope of the invention. Thus, it is intended that the present invention cover the modifications and variations of this invention provided they come within the scope of the appended claims and their equivalents.

What is claimed is:

1. A stacked structure of stackable semiconductor packages, comprising:
a stacked semiconductor package in which a plurality of semiconductor packages are stacked, each semiconductor package having a plurality of external leads at side surfaces thereof; and
conductive wires for electrically connecting the corresponding external leads of said semiconductor packages of said stacked semiconductor package.

2. The stacked structure of the stackable semiconductor packages according to claim 1, wherein said stacked semiconductor package is formed by which semiconductor packages of different size are stacked.

3. The stacked structure of the stackable semiconductor packages according to claim 1, wherein said stacked semiconductor package is formed by which semiconductor packages of the same size are stacked.

4. The stacked structure of the stackable semiconductor packages according to claim 1, wherein each external lead is plated with lead or other conductive material.

5. The stacked structure of the stackable semiconductor packages according to claim 1, wherein each external lead is short formed and its section is concave.

6. The stacked structure of the stackable semiconductor packages according to claim 1, wherein each wire is plated with lead or other conductive material.

7. A method of stacking stackable semiconductor packages, comprising:
stacking a plurality of stackable semiconductor packages by an adhesive member, each semiconductor package having a plurality of external leads at side surfaces thereof;
electrically connecting the corresponding upper and lower external leads of said stackable semiconductor packages in the stacked semiconductor package structure by using a plurality of conductive wires;
reflowing for firmly attaching said wires to the corresponding external leads; and
cutting and removing portions of said wires to electrically insulate the corresponding upper and lower external leads from the adjacent external leads and from the opposite external leads.

8. The method of stacking the stackable semiconductor packages according to claim 7, wherein said semiconductor packages have different size.

9. The method of stacking the stackable semiconductor packages according to claim 7, wherein said semiconductor packages have the same size.

10. The method of stacking the stackable semiconductor packages according to claim 7, wherein each external lead is plated with lead or other conductive material.

11. The method of stacking the stackable semiconductor packages according to claim 7, wherein each external lead is short formed.

12. The method of stacking the stackable semiconductor packages according to claim 7, wherein each external lead has a concave section.

13. The method of stacking the stackable semiconductor packages according to claim 7, wherein each wire is plated with lead or other conductive material.

14. The method of stacking the stackable semiconductor packages according to claim 7, wherein said wires are wound around the stacked semiconductor package at a regular pitch by an automatic wiring apparatus.
